(19) United States
(12) Patent Application Publication
(10) Pub. No.: US 2023/0047568 A1
(43) Pub. Date: Feb. 16, 2023

(54) PRINTED CIRCUIT BOARDS WITH EMBOSSED METALIZED CIRCUIT TRACES

(71) Applicant: Imagine TF, LLC, Campbell, CA (US)

(72) Inventor: Brian Edward Richardson, Los Gatos, CA (US)

(21) Appl. No.: 17/398,491

(22) Filed: Aug. 10, 2021

(51) Int. Cl. H05K 3/10; H05K 1/02; H05K 3/00; H05K 3/46; H05K 3/18; H05K 1/11

(52) U.S. Cl. CPC H05K 3/107; H05K 1/0298; H05K 3/0011; H05K 3/4614; H05K 3/181; H05K 1/111; H05K 1/115; H05K 2201/094; H05K 2201/09227; H05K 2201/09036; H05K 2203/072; H05K 2201/10106

(57) ABSTRACT

A PCB that constructs circuit traces, vias, and connection pads by filling recessed areas, grooves, holes, and/or counter bores with conductive material. The recessed areas are filled with conductive ink or plating solutions by a number of methods. Capillary action aids in the filling of the recessed areas. Pressure, vacuum and or gravity can aid the filling. Layers of the PCB or similar type devices can be bonded together both mechanically and electrically to accomplish 3D connections of circuits. Ground and power plane durability and conductivity is enhanced by the inclusion of small grooves over the conductive plane.

### FIELD OF THE PRESENT DISCLOSURE

The present invention disclosures an architecture for printed circuit boards (PCBs) with conductive circuit traces within grooves in the surface of one or more PCB layers. More specifically, the grooves are preferably formed by embossing the PCB layers and filling the grooves with conductive materials. This type of architecture can be applied to almost all types of PCBs, Systems in a Package (SiPs), and related types of circuit devices.

### SUMMARY

Various embodiments of the present disclosure teach a device generally constructed from at least one PCB layer. The PCB layer includes pads for the connection of circuit devices such as ICs, LEDs, switches, connectors, and other types of electrical components. Most of the pads are connected by circuit traces to one or more other pads for the conduction of electrical signals. In some cases, a multi-layer PCB would have interconnect vias to make connection from one layer to another. All of these traces, pads, and vias are embedded into the PCB layers in the technology disclosed herein. By embedding these elements into the PCB layers, durability is increased over current state of the art PCBs, where those elements are thin, vulnerable metal films positioned atop the surfaces of the PCB layers. By embedding the elements (traces) in the PCB, the thickness (depth of the traces) can be orders of magnitude greater than current state of the art traces. This allows for trace width and spacing to be much less than current state of the art PCBs. Further, current state of the art trace widths is limited to 100 um in width. This width is due to the manufacturing limitations of the process. Embossed grooves can be, and have been, created with widths as small as 10 nanometers and depths up to five times the width. The embossed grooves are filled with conductive material via the insertion of inks, via chemistry methodology, or plating techniques.

Due to the much greater thickness (depth) of the disclosed traces compared to current art devices, the width of the traces can be much smaller while still achieving equivalent electrical conduction. (The total cross-sectional area is the same in the traces disclosed herein and in the current art devices.) The reduced width allows for more densely populated PCB devices.

### BRIEF DESCRIPTION OF THE DRAWINGS

The accompanying drawings, where like reference numerals refer to identical or functionally similar elements throughout the separate views, together with the detailed description below, are incorporated in and form part of the specification, and serve to further illustrate embodiments of concepts that include the claimed disclosure, and explain various principles and advantages of those embodiments.

The methods and systems disclosed herein have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

FIG. 1 is a perspective view of a PCB assembly according to preferred embodiments of the present invention.

FIG. 2 is a perspective view of the PCB board shown in FIG. 1 with the electrical components removed.

FIG. 3 is a detailed perspective view illustrating an area of the PCB board.

FIG. 4 is another detailed perspective view illustrating a different area of the PCB board.

FIG. 5A is a perspective view of the PCB board shown in FIG. 1 with the uppermost circuit layer removed so that a second circuit layer can be seen.

FIG. 5B is a closeup view of a section of the board shown in FIG. 5A.

FIG. 6A is a perspective view of the board shown in FIG. 5A with the second circuit layer removed so a third circuit layer can be seen.

FIG. 6B is a closeup view of a section of the layer shown in FIG. 6A.

FIG. 7A is a perspective view of the board shown in FIG. 6A with the third circuit layer removed so a fourth circuit layer can be seen.

FIG. 7B is a closeup view of a section of the layer shown in FIG. 7A.

FIG. 8 is a closeup perspective view illustrating a portion of an uppermost circuit layer before the layer is laminated to other circuit layers, metalized, or drilled.

FIG. 9A is a cross section view of the PCB board shown in FIG. 8 after holes have been drilled through the layers and before metallization.

FIG. 9B is the same cross section shown in FIG. 9A after the metallization process.

FIG. 10 is a perspective view of an alternate embodiment of a circuit layer.

FIG. 11 is a closeup perspective view of an alternate embodiment of a PCB board.

FIGS. 12A and 12B show an alternate embodiment of the invention where electrical components are located within circuit layers

FIG. 13 shows another alternate embodiment of the invention where LEDs are are located within circuit layers.

FIG. 14 is a closeup perspective view of a section of the device illustrated in FIG. 13.

FIGS. 15A and 15B show individual layers of the device shown in FIG. 14.

### DETAILED DESCRIPTION

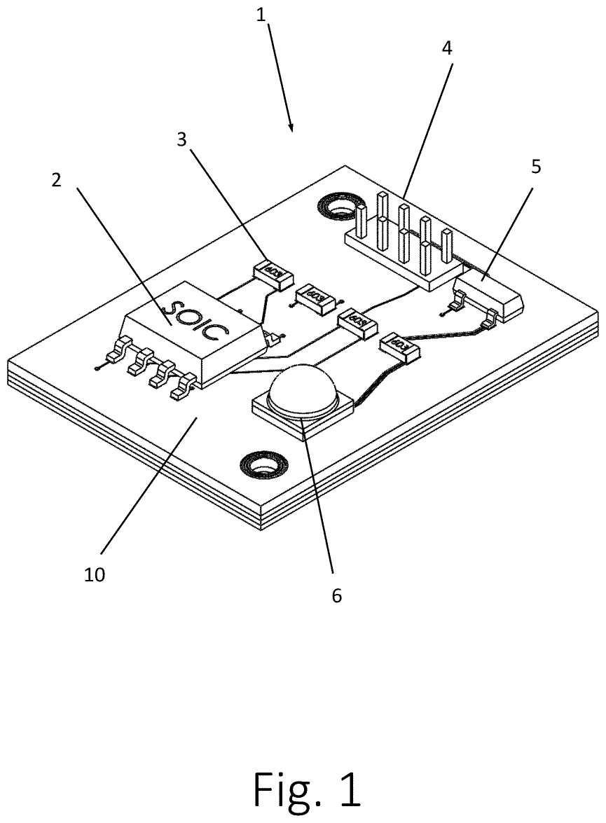

FIG. 1 is a perspective view of a PCB assembly 1 with various electrical components assembled onto it. A number of different types of electrical components are shown; an IC 2, passive devices 3, a connector 4, a transistor 5, and an LED 6. These and other components are well known to those skilled in the art of the electronics industry. The components are typically soldered to a PCB board 10 with a metal-based solder. In many cases, components can be fastened to the surface of the PCB board 10 via the application of conductive ink. One skilled in the art of electronic circuitry could configure devices in an unlimited number of configurations to accomplish the functions of the PCB assembly 1.

Two mechanical types of components are shown, a through hole type component and a surface mount device (SMD) type. The connector 4 is of the through hole type. The connector 4 has pins that extend through holes in the PCB board 10. The pins make electrical and mechanical connections via the above-mentioned solder or ink. The SMD type devices generally have rectangular shaped pads that connect to corresponding pads on the PCB board 10. Mechanical and electrical connections are made by filling the gaps between the pads with solder or conductive ink.

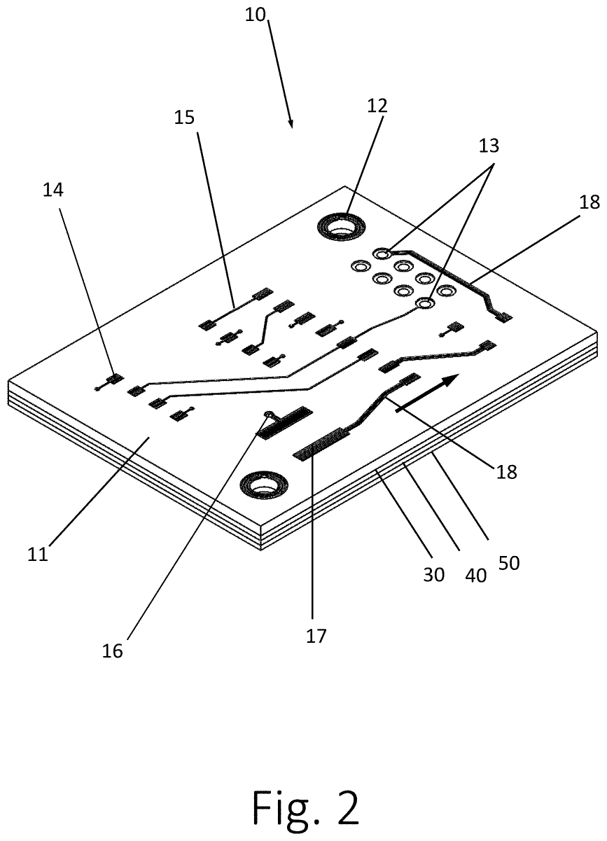

Referring now to FIG. 2, a perspective view of the PCB board 10 with the components removed is shown. The PCB board 10 is constructed with multiple circuit layers. A first circuit layer 11 sits atop further circuit layers. A total of four circuit layers are shown in the drawings. It will be readily recognized by those skilled in the art that many more layers could be deployed. The actual number of layers used in a given PCB assembly is determined by the requirements of a given PCB.

With the components removed in FIG. 2, the details of the PCB board 10 can be more clearly seen. Mounting holes 12 can be deployed for fastening the PCB board 10 to another mechanical component (not shown). Multiple lead holes 13 allow for the connection of through hole type components to traces and to other circuit layers. One of the lead holes 13 is shown as being connected to a wide circuit trace 18. Lead holes 13 can also connect to standard circuit traces 15 if required. Pads 14 are used to make connections with electrical components, and in some cases can be used to make electrical connections to standard circuit traces 15 or wide circuit traces 18. The size of the pads 14 is driven by the type of component that is connected to the pads 14. Elongated pad 17 is an example of a pad with a width much greater than its length. Traces 15 are narrow when the electrical current they are conducting is low. This allows for the traces 15 to be densely spaced on the surface of the board 10.

Wide circuit trace 18 is a trace that is wider than a standard trace, thereby allowing a greater amount of electrical current to flow therethrough. The width of the trace 18 is engineered for the needs of a given implementation. Vias 16 are required to connect circuitry on the first circuit layer 11 to successive layers below. It should be noted that the surfaces of the traces, pads, and vias are typically coated with a conductive material or materials. The remaining areas of the circuit layer 11 are not conductive. These two types of areas (conductive and non-conductive) allow for the control of electrical signals over the PCB assembly 1 and to and from the different electrical components.

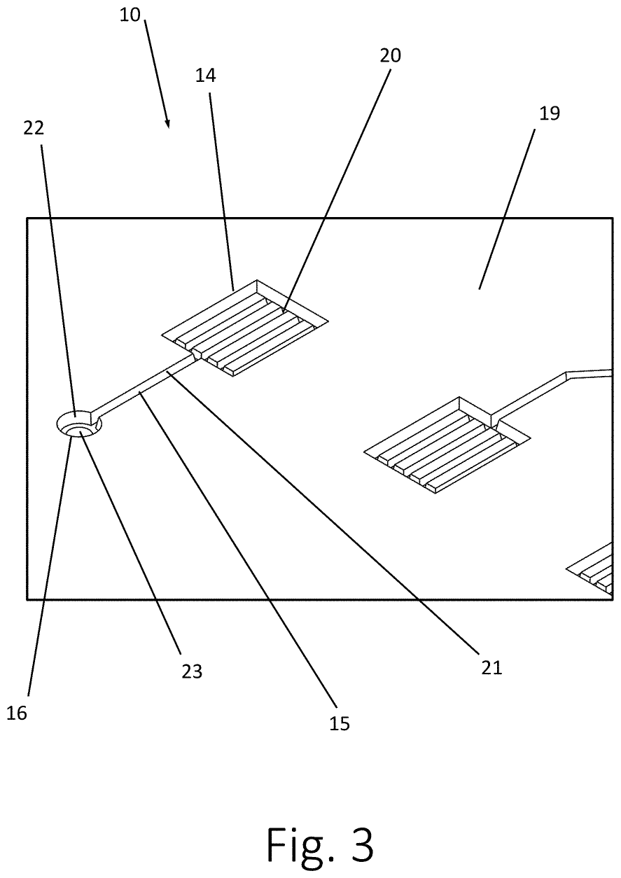

Referring now to FIG. 3, an area of the PCB board 10 can be seen in a closeup view. In the closeup view of FIG. 3, the details of the pads 14, traces 15, and vias 16 can be seen. Pad 14 includes pad grooves 20 in the surface of the first substrate 19. The pad grooves 20 serve three purposes: the pad grooves 20 aid in the manufacturing process, they increase the durability of the pads 14, and they increase the electrical current carrying capacity of the pads 14. Circuit traces 15 are also constructed with trace grooves 21. The circuit trace 15 is shown to be connected to the via 16. Via 16 includes a plated counter bore 22 and a plated hole 23. It should be noted that all of the recessed areas; pads 14, traces 15 and 18, and vias 16 are typically covered with a conductive material to provide electrical conductivity.

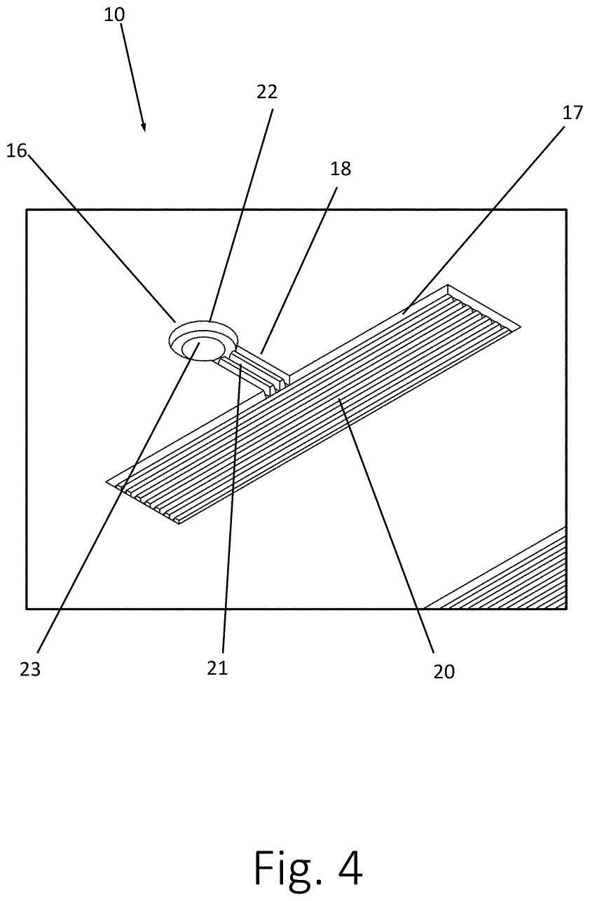

FIG. 4 shows a wide circuit trace 18 connected to an elongated pad 17. The wide circuit trace 18 is constructed with three trace grooves 21. The trace grooves 21 are parallel to one another and are in close proximity to one another. The parallel groove configuration allows the trace 18 to have a greater capacity to carry electrical current. More grooves 21 can be deployed to provide an even greater electrical current conduction capacity.

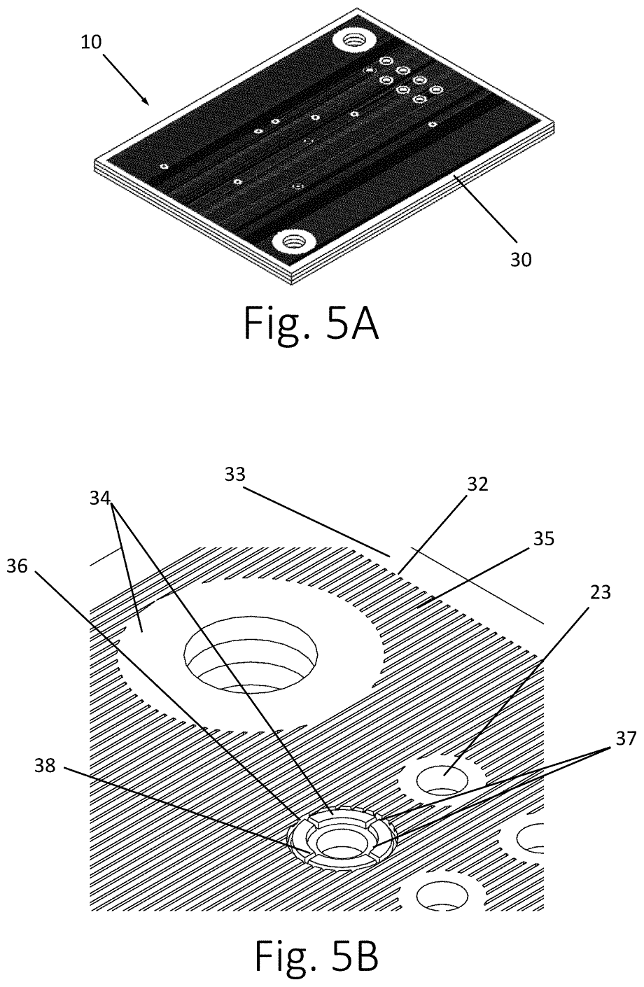

Referring now to FIGS. 5A and 5B, the PCB board 10 is shown with the first circuit layer 11 removed so that the features of a second circuit layer 30 can be seen. The second circuit layer 30 is shown with almost its entire upper surface being formed from a conductive surface 32. Most of the remaining (non-conductive) surface of the second circuit layer 30 is an insulating border 33 and insulated hole pads 34. In the embodiment illustrated, the conductive surface 32 distributes the “ground” electrical connections to the electrical devices. The surface of the conductive surface 32 is populated with a plurality of micro grooves 35. Both the conductive surface 32 and the micro grooves 35 have conductive surfaces. As with the previously discussed pad and trace grooves 20, 21, the micro grooves 35 aid manufacturing, durability, and conductivity of the PCB assembly 1. In the case where an electrical connection is made to a plated hole 23 at either a lead hole 13 or a via 16, a thermal insulator 36 is deployed. The thermal insulator 36 is formed from two concentric annular rings 37 connected with four radial grooves 38. All of the surfaces of the annular rings 37 and radial grooves 38 of the thermal insulator 36 are conductive. The conductive surfaces are continuous with the plated holes 23 and the conductive surface 32. The four areas between the annular rings 37 and the radial grooves 38 are not electrically conductive. Typically, electrical conductors are thermally conductive while electrical insulators are much less thermally conductive. The radial grooves 38 allow for sufficient electrical conduction while limiting thermal conduction from the metal conducting plane 32 which is massive relative to the plated holes 23. This architecture is important when electrical components are soldered to the PCB 10. Current art PCBs deploy only metal films on their surfaces without the utilization of grooves.

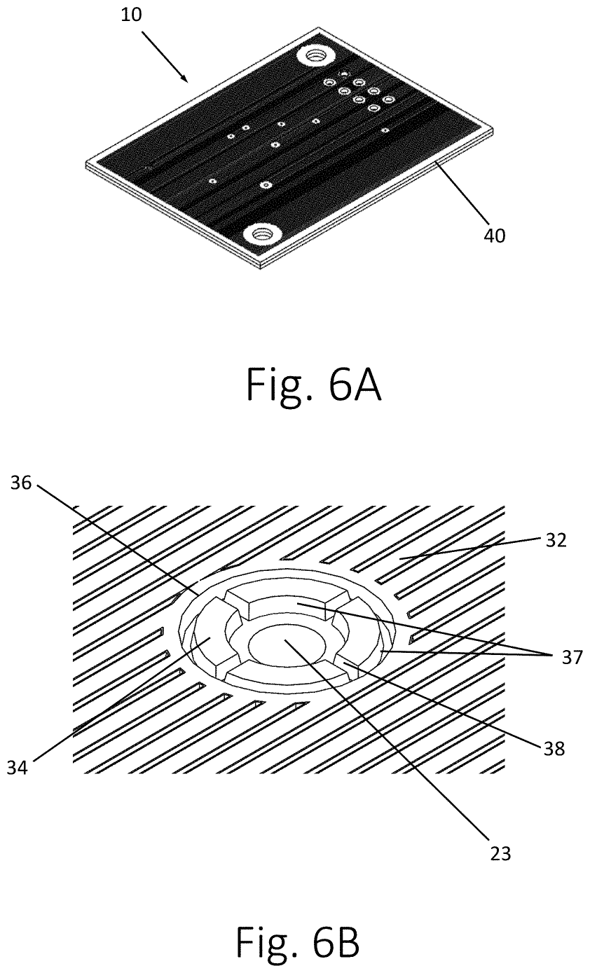

Referring now to FIGS. 6A and 6B, a third circuit layer 40 is shown in detail view. In this view, one can see the connection of the thermal insulator 36 to a different hole, a plated power hole 23. In this case the power is being conducted on the conductive surface 32. More circuit layers can be deployed to supply different voltages or to have multiple grounded areas for different groups of circuit components. For grooved film manufacturing and capillary filling of the grooves, it is generally desirable to have the width and depth of the grooves be the same for the entire surface of a given board layer.

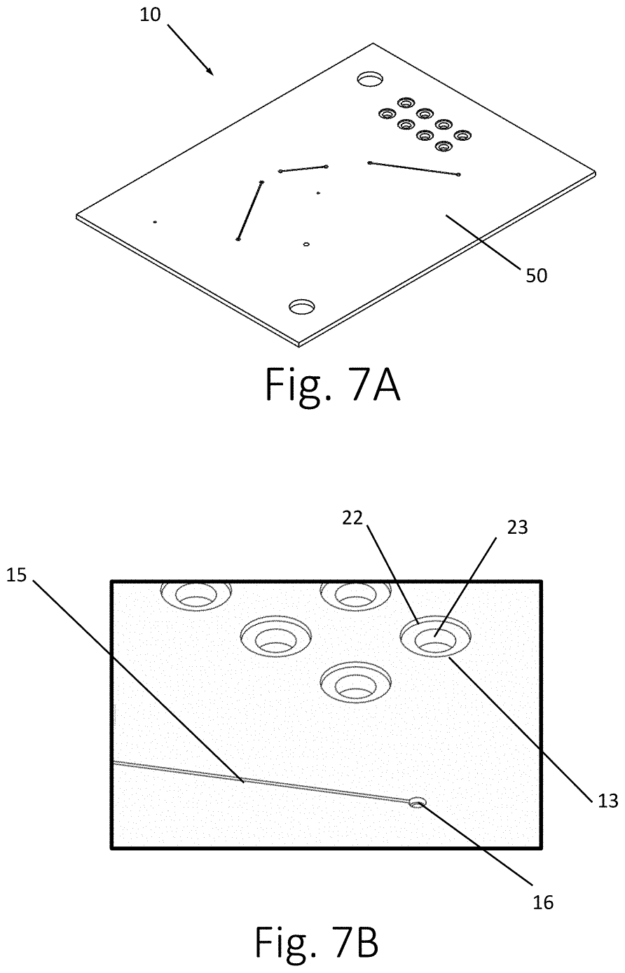

FIG. 7 shows a fourth circuit layer 50, with no other layers shown. The fourth circuit layer 50 does not have pads in the areas below SMD components. Pads are not required on circuit layer four 50 due to the fact that the electrical components do not make direct contact. Vias 16 are present to connect circuit traces 15, 18 from one via 16 to another. Circuit traces 15, 18 could be deployed to connect a via 16 to a though hole pad or to connect two pads to one another. The circuit traces 15, 18 and pads on the fourth circuit layer 50 are of the same architecture, and include metallized grooves as on the preceding layers of the device. The vias 16 on the fourth circuit layer 50 make electrical connection to other layers by means of the plated holes 23 and plated counter bores 22.

All of the multiple circuit layers of the PCB are typically bonded together. The bonding can be done with an adhesive or by other means know to those skilled in the art of PCB manufacture. It should be noted that the PCB assembly 1 described herein is not particularly complex. Many PCB assemblies are far more complex and include have many more components, and have more complex components. A PCB board used for such complex assemblies might require ten or more circuit layers to connect all of the required components and to deliver multiple required voltages.

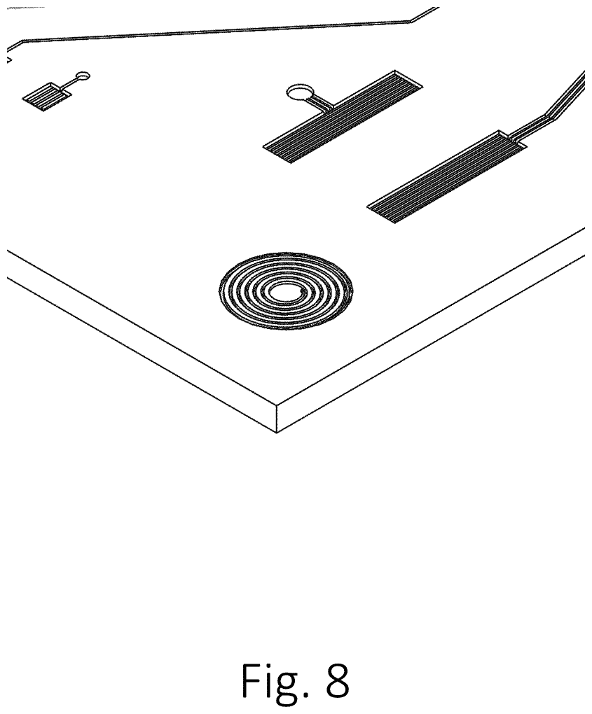

FIG. 8 shows a first circuit substrate 19 at an intermediate stage of fabrication. First circuit substrate 19 is the substrate for a first circuit layer without conductive surfaces and before the drilling of holes. This circuit substrate 19 would preferably be fabricated with a plurality of recessed grooves. One suitable means for construction of the grooves is embossing. Embossing is a process widely used to form micro or even nanometer scale features in a polymer. U.S. Pat. No. 5,772,905, inventor Stephen Chou, issued Jun. 30, 1998, describes the fabrication of embossed features smaller than 25 nm wide. More recently, single digit nanometer grooves have been produced by a large number of researchers and inventors. More importantly, many companies have been able to manufacture nanometer scale features in high volume. The holographic elements on currency and credit cards are examples of extremely high-volume low-cost embossed structures on the surface of a substrate. The grooves can be fabricated such that their depth is much greater their width. For high volume production of PCB boards, the embossed substrates can be fabricated with roll-to-roll equipment. High speed roll-to-roll fabrication equipment can produce meters of film in seconds. Hot embossing, epoxy embossing, and UV cure embossing are three common methods of producing grooves in a PCB board. Injection molding is another possible manufacturing method. Compression molding is another method that could be used to emboss ceramic substrates. An alternate manufacturing process to fabricate channels is to ablate them with a laser beam.

There are many options for materials that can be used to form the substrate. One skilled in the art of PCB board manufacturing would readily understand the factors involved in the choice of material for a given application. Almost any type of insulating material can be deployed as a circuit substrate including but not limited to polymers, ceramics, glass, and dielectric semiconductor materials.

The conductive surfaces in the circuit layers can be created in a number of ways. The preferred method is to dispense liquids to the grooved areas. Different methods can be deployed to do this: needles, inkjet, and conventical type printing can be deployed. The grooves aid in the distribution of liquids to the intended areas (conductive surfaces to be formed) and aid in excluding the liquid from unintended areas (nonconductive surfaces). Capillary action is the physical force that drives the movement of the liquids in the grooves. Capillary action can cause liquid to move within the grooves and fill them with conductive material, even when the conductive material is not directly applied to the desired area. In many cases the liquid may only need be applied at the ends of the trace grooves, pads, or vias. Capillary action draws the liquid down the grooves to entirely fill them. The filling force of capillary action is greater for smaller channel widths. This is ideal for circuit formation. The current art for PCB circuit traces is 100 um wide. Embossed groove channels filled with capillary action can be much smaller than that.

The surface tension of the grooves, which may be embossed channels, also affects the capillary force. Those skilled in the art of surface tension and capillary action can readily devise appropriate chemistries choosing the substrate material, substrate surface characteristics, and the liquid used to fill the grooves to maximize capillary force. External pressure, a vacuum, gravity, and/or force derived from motion can also be used to enhance the filling of the grooves.

The dispensed liquid used to fill the grooves in the surface of the PCB to create the conductive surfaces can be any one of a number of solutions. The preferred solution is a catalyst liquid that creates a surface that can be electroless plated with copper or other conductors. The catalyzed surfaces coming into contact with a catalyzed solution enables chemical plating. Surfaces that have not been catalyzed will not plate during the plating process. Therefore, the grooves, pads, and vias are filed with a catalyzing solution to readily enable chemical plating. Surfaces that are not desired to be conductive are left uncatalyzed, and are therefore not affected during the plating process. The uncatalyzed surfaces do not form and retain a conductive surface. The areas of conductivity selectively created by the catalyzed surfaces allows for the submersion of the entire substrate in a chemical plating solution for the plating process. The noncatalyzed areas on the substrate do not plate where the substrate surface is not catalyzed. The surface catalyzation and plating of a substrate generally requires a number of process steps, including: (1) Cleaning and or etching of the substrate; (2) Neutralizing; (3) Catalyzing; (4) Activating; and (5) Electroless plating.

An alternate method of fabrication would be to catalyze the entire surface of the substrate and then selectively plate the grooves. Still another method of creating the desired conductive areas would be electroplating. Electroplating requires an electrical connection to the areas to be plated. With some circuit designs, the required electrical connections are easily established. With other designs, it is far more challenging. The circuit design for a given implementation drives what type of plating is deployed. Electroplating can be used to plate more than one type of material. The material may be chosen according to the requirements of a given desired product. Gold, for example may be applied for corrosion resistance, tin for solder adhesion and flow, and nickel for durability.

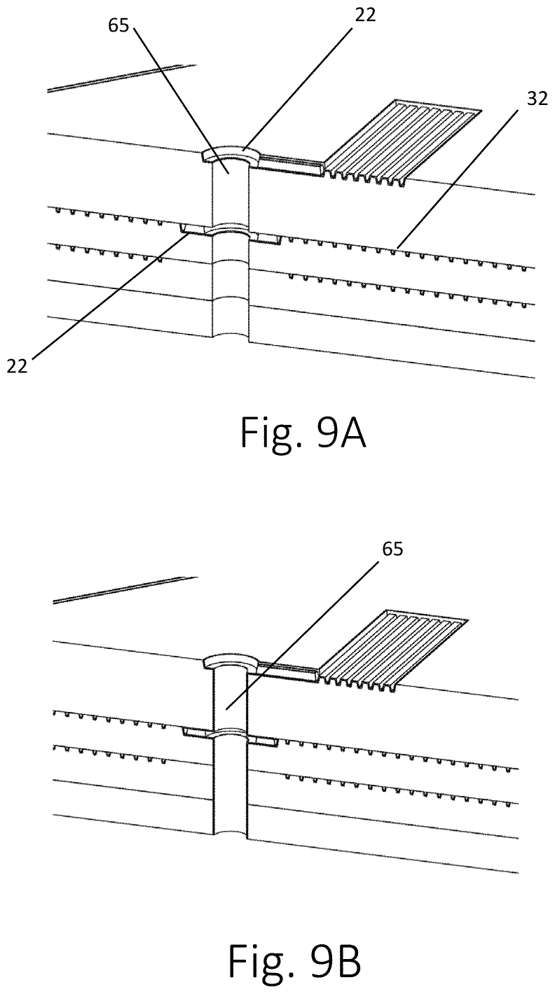

FIG. 9A shows a board on which all of the circuit layers have been laminated to one another and drilled. All of these layers were embossed and metalized by a process disclosed in the fabrication discussion above. The layers can be laminated one at a time or all together. FIG. 9A shows the addition of drilled holes 65 over FIG. 8. The holes 65 are preferably drilled after the lamination process; however, the holes 65 can be drilled before the lamination process. The term “drilling” does not limit the fabrication method. Molded, embossed, punched, or laser ablated holes would also suffice. The drilled holes 65 allow for the electrical connection of one layer to another.

FIG. 9B shows the holes 65 of FIG. 9A following metallization of the vias and holes 65 to connect the circuit layers. The metallization process used to electrically connect the circuit layers is generally the same as the process described above for the metallization of the grooves and pads.

Most PCB boards would also include a solder mask coating and printed nomenclature. These same processes may be added to the disclosed PCB board and are not presented in this disclosure as they are well known in the art.

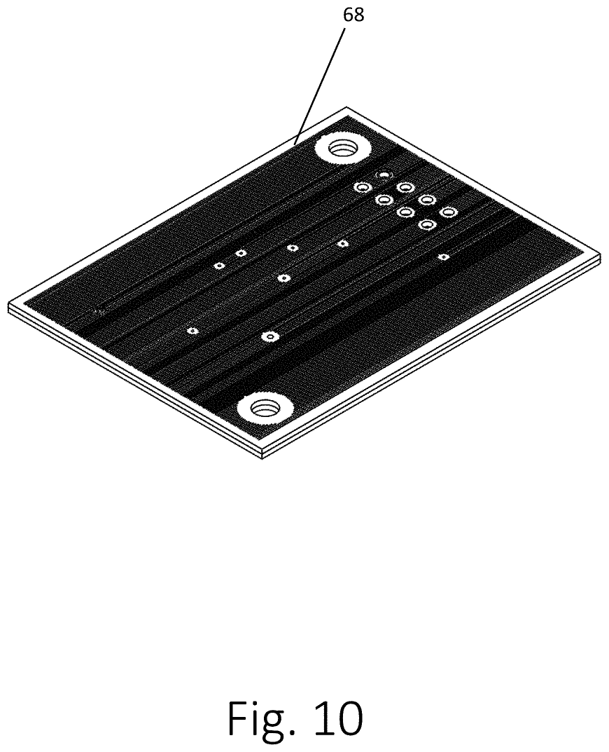

FIG. 10 discloses an alternate embodiment of the ground or power plane. The plane portion of the conductive area 68 does not have grooves, but rather is simply a printed conductive surface 68. As mentioned above, the micro grooves improve conductivity and durability. In some cases, these attributes are not required, and simple printing of the catalyst and plating (as suggested by FIG. 10) would be sufficient. Conventional type etched circuit layers could also be substituted for the disclosed plane type circuit layers.

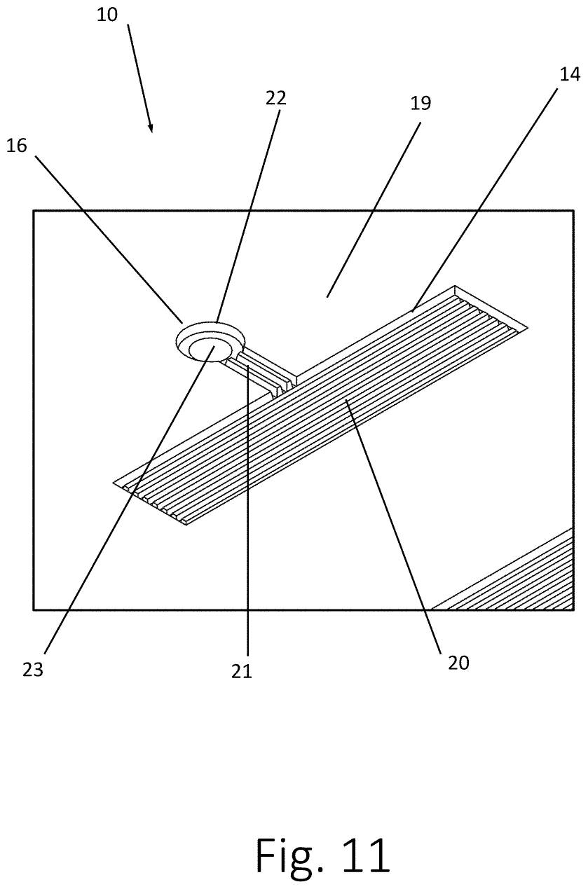

FIG. 11 shows another alternate embodiment of the present invention. In the embodiment shown in FIG. 11, the catalyst solution is applied, and the subsequent chemical plating is done after the substrate layers have been laminated. With this approach the catalyzing and plating solution would be applied only at the pads or lead holes. The solutions would flow through the traces to vias and/or holes to the internal layers and out the holes and vias on the last layer. Manifolds that are gasketed to the top and bottom sides of the PCB boards can be deployed to accomplish the plating. One skilled in the art of selectively delivering solutions could devise other methods to accomplish the task of metalizing the intended surfaces.

An alternate embodiment for metallization is the substitution of conductive ink for one or both of the catalyzing and plating processes. Conductive ink can also be used for just the plane metallization. Just as there is a large number of suppliers for plating chemicals there are also many suppliers of conductive inks and related types of materials.

In sum, fabrication may be accomplished by several methods. A preferred embodiment of fabrication utilizes the following steps: (1) Emboss a substrate with traces and counterbores; (2) Metalize embossed channels and counterbores; (3) Repeat steps 1 & 2 for all layers; (4) Laminate all layers together; (5) Drill holes and vias as required; and (6) Metalize vias and holes.

An alternate preferred embodiment for the fabrication process includes the following steps: (1) Emboss a substrate with traces, vias, holes and counterbores; (2) Repeat steps 1 & 2 for all layers; (3) Laminate all layers together; (4) Drill additional holes and vias if needed; and (5) Metalize all traces, vias and holes by forcing liquids through all of the traces, vias and holes in all of the layers.

A second alternate preferred embodiment for the fabrication process includes the following steps: (1) Emboss the base substrate with traces and counter bores; (2) Create holes including via holes as needed; (3) Metalize embossed channels, counterbores, vias and holes; (4) Emboss another substrate with traces and counter bores; (5) Create holes including via holes as needed in the substrate; (6) Laminate the substrate to the previous substrate(s); (7) Metalize embossed channels, counterbores and holes (vias and holes are metalized down to lower layer(s)) making connections to the lower layers; and (8) Repeat steps step 4 through 6 as required.

Metallization may also be accomplished by several methods. The method chosen depends on the parameters of the given construction required. One preferred embodiment of metallization utilizes the following steps: (1) Activate only the surfaces to be metalized with a catalyst containing a noble metal; and (2) Chemically plate the catalyzed surfaces with a metal. Note that the only the catalyzed surfaces will be plated. This allows for the entire part to be submerged in the plating solution.

An alternate preferred embodiment for the metallization process includes the following steps: (1) Activate the entire part with a catalyst containing a noble metal; and (2) Selectively chemically plate the catalyzed surfaces with a metal. The surfaces that are not to be plated need to be masked to keep them from being plated.

Another alternate preferred embodiment for the metallization process includes the following steps: (1) Coat the surfaces that are not to be plated with a sacrificial material; (2) Activate the entire part with a catalyst containing a noble metal; (3) Remove the sacrificial material thereby removing the catalyzed surfaces in the areas that are not to be metalized; and (4) Chemically plate the remaining catalyzed surfaces with a metal. Note that the only the catalyzed surfaces will be plated. This allows for the entire part to be submerged in the plating solution.

Still another alternate preferred embodiment for the metallization process includes the following steps: (1) Partially metalize the surfaces to be plated with a conductive ink or a solution, nano particles, or a conductive material; and (2) Chemically plate the metalized surfaces with another metal. Note that the only the previously metalized surfaces will be plated. This allows for the entire part to be submerged in the plating solution.

Yet another alternate preferred embodiment for the metallization process includes metallizing the desired surfaces with a conductive ink, nano particles, or a conductive material.

It should be noted that the systems and methods described above yield a significant advantage in the fabrication of PCB assemblies. With current art technology, traces are typically 100 um in width. With the technology disclosed herein, equivalent conductivities are achieved with trace widths of less than 1 um. The reduced width allows for much more compact arrangement of circuitry, and therefore the construction of much smaller electronic devices. The dimensions cited above are illustrative only. Many variations of trace and pad widths can be made while adhering to the teachings herein. These numbers are recited only to illustrate that with present technology, conductive surfaces can be made much more narrow while maintaining equivalent conductivity by increasing the depth of the groove used to form the conductive trace or pad.

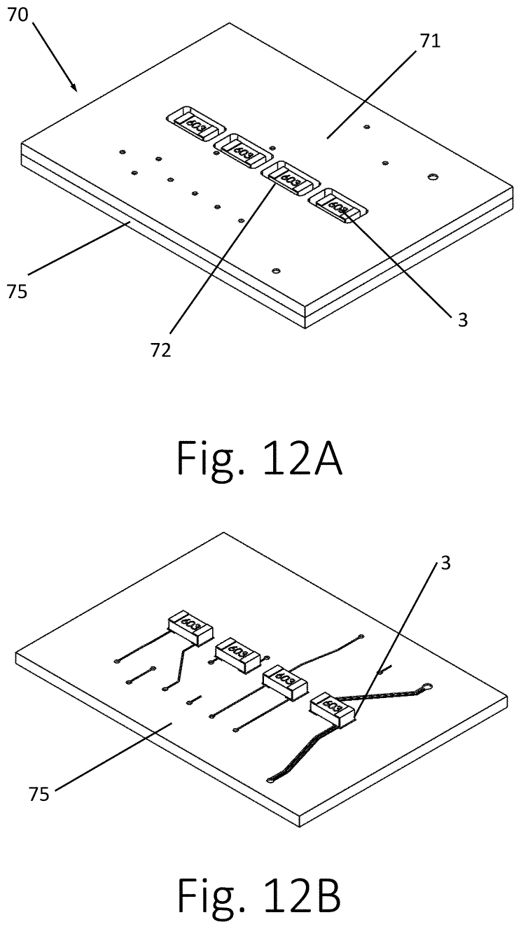

FIGS. 12A and 12B illustrate a PCB assembly with components embedded between circuit layers. Embedded chip PCB 70 is shown without a top layer. The top layer could be of the type discussed above. The embedded chip PCB 70 includes a spacer layer 71 and a lower circuit layer 75. The spacer layer 71 is similar in thickness to the passive devices 3. While passive devices 3 are shown in FIGS. 12A and 12B, other types of circuit components could just as easily be deployed. The spacer layer 71 has spacer openings 72 to accommodate the multiple passive devices 3. The spacer openings 72 can be the same size as the perimeter of the passive device 3 to help locate the passive device 3, or they can be larger, as shown, to allow an external mechanism to locate the passive device 3 to the pads on the lower circuit layer 75.

The relationship of the passive devices 3 to the lower circuit layer 75 can best be seen in FIG. 12B. The passive device 3 can be fastened and electrically connected to the pads with solder, made of conductive ink, or by applying a mechanical force to make mechanical and electrical contact with the associated pads. The required force can be created by a slight interference fit of the height of the passive devices 3 relative to the PCB layer stack.

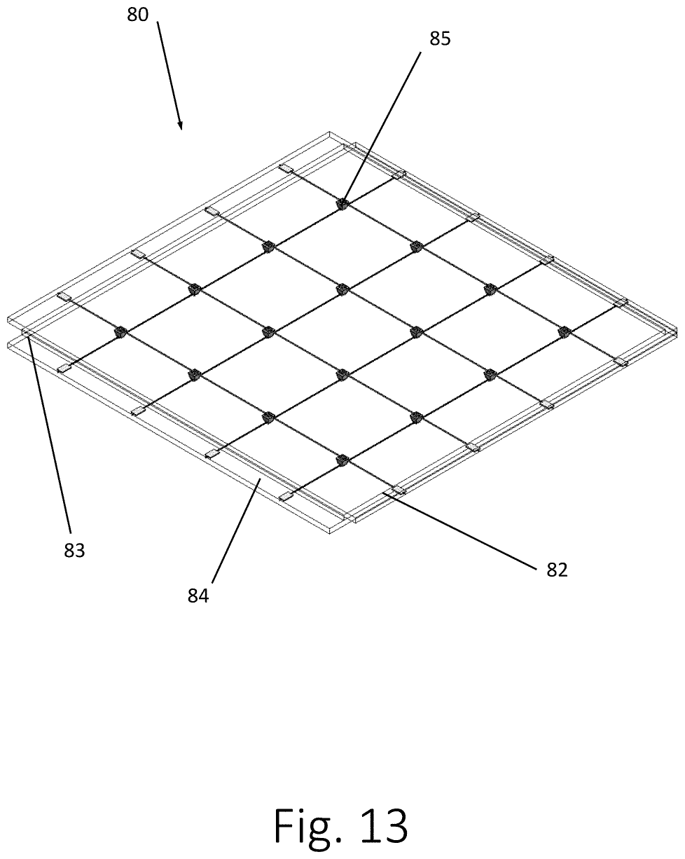

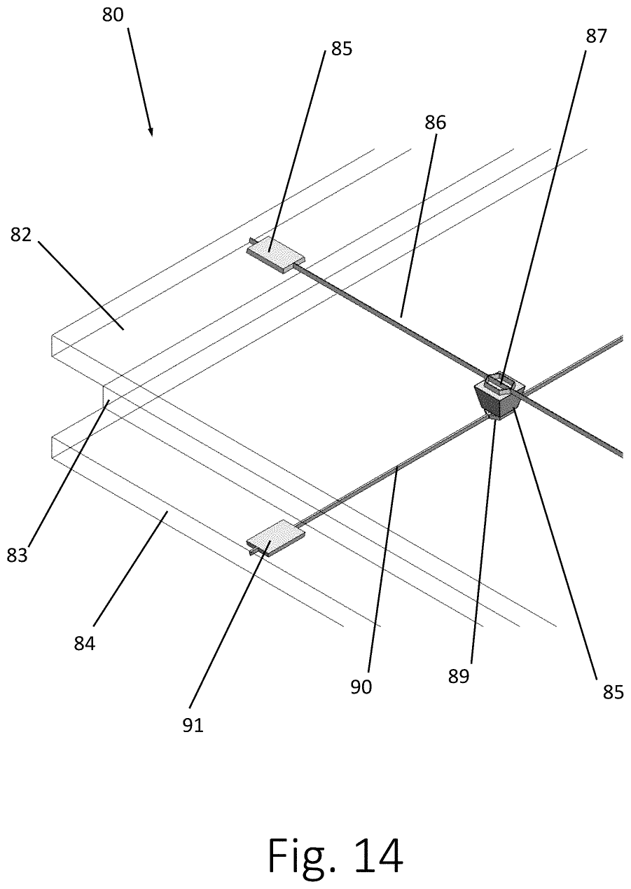

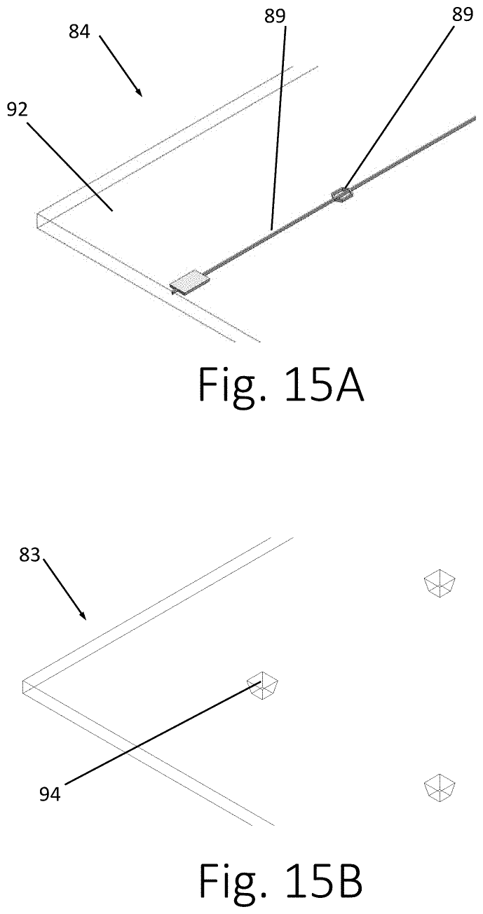

Referring to FIG. 13, yet another embodiment of the PCB assembly is shown, LED PCB assembly 80. LED dies 85 are embedded between transparent circuit layers as illustrated. This embodiment is representative of the invention as it would be used in a display or lighting application. The top layer 82 has circuit traces and pads located on its bottom surface. These elements make electrical contact with the top surface of the LED die 85. The LED spacer layer 83 is situated between the top layer 82 and the bottom layer 84. More detail of these components can be seen in FIGS. 14, 15A, and 15B. The layers are shown in the drawings as transparent material.

The top layer circuit elements—top layer connection 85, top layer traces 86, top layer pads 87—and the corresponding bottom layer components—bottom layer pads 89, bottom layer traces 90, and bottom layer connections 91—are metallic and are not shown as transparent. These metallic features make electrical connections from the LED die 85 to the edges of the LED PCB assembly 80.

An electrical signal is typically delivered to the edge of the LED PCB assembly 80 at the top layer connection 85. The top layer connection 85 is large relative to the other circuit elements to reduce the need for accuracy in aligning an external connection to the top layer connection 85. The top layer trace 86 conducts the electrical signal from the top layer connector 85 to the top layer pads 87. The top layer pads 85 deliver the signal to the top surface of the LED die 85. The signal conducts through the LED die 85 to the bottom layer pad 89. The conducted signal enables the production of light by the LED die 85. The signal is conducted to the bottom layer tracer 89 and then to the bottom layer connection 91. As with the top layer, the bottom layer would be connected to an external device that creates the electrical signal.

The traces are shown to be much more narrow than they are deep. This allows for high electrical conductivity with high optical clarity. Both are generally desired elements of an LED type device.

The top layer and bottom layer pads are shown to have multiple grooves in parallel. The actual number of grooves associated with the pads would be a function of the needs of the LED die 85 and the extraction of light from the LED die 85. The top layer pads 87 might be limited in size to maximize light output. The bottom side layer pads 89 may not need to allow light output. In fact, the bottom side layer pads 89 can be continuous or even larger than the LED die to reflect light to the top side of the LED PCB assembly 80.

The LED die 85 is shown to have tapered sides. This attribute aids in the assembly of the die to the LED spacer layer 83. The LED spacer layer 83 can be seen by isolated in FIG. 15B. The tapered construction allows for self-assembly of the devices rather than placing them individually. To ensure electrical connection of the pads to the LED die 85, the LED spacer layer 83 is slightly thinner than the LED die 85. This would provide a compressive force at the connections of the LED die 85 to the top and bottom layer pads.

The metal plating of the pad traces is preferably thick enough that the metal surface extends slightly above the surface of the corresponding layer to ensure there is a good electrical connection between the LED die and pads.

Conductive ink could also be deployed to make the electrical connections between the LED die 85 and the top and bottom layer pads.

For a color display application, three of the LED PCB assemblies 80 would be deployed. One device would be configured with red LED dies, the second with green dies, and the third with blue.

Many of the disclosed LED PCB assemblies can be laminated together to form a 3D array of LEDs. This 3D array can be used to produce 3D images.

The description of the present disclosure has been presented for purposes of illustration and description, but is not intended to be exhaustive or limited to the present disclosure in the form disclosed. Many modifications and variations will be apparent to those of ordinary skill in the art without departing from the scope and spirit of the present disclosure. Exemplary embodiments were chosen and described in order to best explain the principles of the present disclosure and its practical application, and to enable others of ordinary skill in the art to understand the present disclosure for various embodiments with various modifications as are suited to the particular use contemplated.

While this technology is susceptible of embodiment in many different forms, there is shown in the drawings and will herein be described in detail several specific embodiments with the understanding that the present disclosure is to be considered as an exemplification of the principles of the technology and is not intended to limit the technology to the embodiments illustrated.

The terminology used herein is for the purpose of describing particular embodiments only and is not intended to be limiting of the technology. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that like or analogous elements and/or components, referred to herein, may be identified throughout the drawings with like reference characters. It will be further understood that several of the Figures are merely schematic representations of the present disclosure. As such, some of the components may have been distorted from their actual scale for pictorial clarity.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” or “according to one embodiment” (or other phrases having similar import) at various places throughout this specification are not necessarily all referring to the same embodiment. Furthermore, the particular features, structures, or characteristics may be combined in any suitable manner in one or more embodiments. Furthermore, depending on the context of discussion herein, a singular term may include its plural forms and a plural term may include its singular form. Similarly, a hyphenated term (e.g., “on-demand”) may be occasionally interchangeably used with its non-hyphenated version (e.g., “on demand”), a capitalized entry (e.g., “Software”) may be interchangeably used with its non-capitalized version (e.g., “software”), a plural term may be indicated with or without an apostrophe (e.g., PE's or PEs), and an italicized term (e.g., “N+1”) may be interchangeably used with its non-italicized version (e.g., “N+1”). Such occasional interchangeable uses shall not be considered inconsistent with each other.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It is noted at the outset that the terms “coupled,” “connected”, “connecting,” “electrically connected,” etc., are used interchangeably herein to generally refer to the condition of being electrically/electronically connected. Similarly, a first entity is considered to be in “communication” with a second entity (or entities) when the first entity electrically sends and/or receives (whether through wireline or wireless means) information signals (whether containing data information or non-data/control information) to the second entity regardless of the type (analog or digital) of those signals. It is further noted that various Figures (including component diagrams) shown and discussed herein are for illustrative purpose only, and are not drawn to scale.

While specific embodiments of, and examples for, the system are described above for illustrative purposes, various equivalent modifications are possible within the scope of the system, as those skilled in the relevant art will recognize. For example, while processes or steps are presented in a given order, alternative embodiments may perform routines having steps in a different order, and some processes or steps may be deleted, moved, added, subdivided, combined, and/or modified to provide alternative or sub-combinations. Each of these processes or steps may be implemented in a variety of different ways. Also, while processes or steps are at times shown as being performed in series, these processes or steps may instead be performed in parallel, or may be performed at different times.

What is claimed is:

1. A method of constructing a PCB assembly comprising:
using a first substrate with one or more grooves cut beneath an outer surface on at least one side of the substrate, the grooves being at least partially filled with conductive material to form a circuit layer of circuit conductors that provide electrical connections for the PCB assembly to connect to at least one other electronic device.

2. The method according to claim 1, wherein the grooves in which the circuit conductors are formed are deeper than they are wide.

3. The method according to claim 1, wherein at least a second substrate is bonded to the first substrate, and at least one of the conductors formed on the first substrate is connected to a conductor on the second substrate via a through hole.

4. The method according to claim 1, wherein a thin layer of metal is deposited by a chemical solution on the surface of at least one of the grooves to facilitate the deposition of another metal on the thin layer of metal by a plating process.

5. The method according to claim 1, wherein multiple circuit layers are bonded together.

6. The method according to claim 1, wherein the circuit conductors include at least one of traces and pads.

7. A method of constructing a PCB assembly comprising:
forming a first substrate with a plurality of grooves on at least one side, the grooves being arrayed in close proximity to one another to create an electrical circuit plane, the electrical circuit plane being electrically connected to at least a second substrate with a plurality of grooves therein, each circuit plane being devoid of conductive material where no electrical connection is desired.

8. The method according to claim 7, wherein the grooves are deeper than they are wide.

9. The method according to claim 7, wherein the electrical circuit plane is connected to a via or hole via a web of traces formed around an annulus.

10. The method according to claim 7, wherein a thin layer of metal is deposited by a chemical solution on the surface of at least one of the grooves to facilitate the deposition of another metal on the thin layer of metal by a plating process.

11. The method according to claim 10, wherein the thin layer of metal is deposited by a catalytic solution.

12. A circuit device comprising:
a first substrate with grooves on at least one side that are at least partially filled with conductive material to form circuit conductors that make electrical connections from a first circuit device to a second circuit device.

13. The device according to claim 12, wherein the traces are deeper than they are wide.

14. The device according to claim 11, wherein at least a second substrate is bonded to the first substrate, and at least one of the conductors formed on the first substrate is connected to a conductor on the second substrate via a through hole.

15. The device according to claim 11, wherein multiple circuit layers are bonded together.

16. A circuit device comprising:
a substrate with a plurality of grooves on at least one side, the grooves being arrayed in close proximity to one another to create an electrical circuit plane, the electrical circuit plane being electrically connected to at least a second substrate with a plurality of grooves therein, each circuit plane being devoid of conductive material where no electrical connection is desired.

17. The device according to claim 16, wherein the grooves are deeper than they are wide.

18. The device according to claim 16, wherein the electrical circuit plane is connected to a via or hole via a web of traces formed around an annulus.

19. The device according to claim 16, wherein a thin layer of metal deposited by a chemical solution on the surface of at least one of the grooves serves as a substrate for the deposition of another metal on the thin layer of metal by a plating process.

20. The device according to claim 19, wherein the thin layer of metal is deposited by a catalytic solution.
